(19) United States
(12) Patent Application Publication
(10) Pub. No.: US 2026/0011601 A1
(43) Pub. Date: Jan. 8, 2026

(54) SEMICONDUCTOR DEVICE HAVING AIR GAP STRUCTURE AND METHOD FOR MANUFACTURING THE SAME

(71) Applicant: Taiwan Semiconductor Manufacturing Company, Ltd., Hsinchu (TW)

(72) Inventors: Wei-Hao LIAO, Hsinchu (TW); Hsi-Wen TIEN, Hsinchu (TW); Chih Wei LU, Hsinchu (TW); Hwei-Jay CHU, Hsinchu (TW); Wei-Chih WANG, Hsinchu (TW); Yu-Teng DAI, Hsinchu (TW); Hsin-Chieh YAO, Hsinchu (TW); Cheng-Hao CHEN, Hsinchu (TW)

(73) Assignee: Taiwan Semiconductor Manufacturing Company, Ltd., Hsinchu (TW)

(21) Appl. No.: 18/761,929

(22) Filed: Jul. 2, 2024

(51) Int. Cl. H01L 21/768; H01L 23/532

(52) U.S. Cl. CPC H01L 21/7682; H01L 21/76832; H01L 23/5329

(57) ABSTRACT

A semiconductor device includes a substrate, a conductive interconnect structure disposed on the substrate, a plurality of air gap structures disposed on the conductive interconnect structure and spaced apart from each other, and a plurality of conductive interconnects disposed on the conductive interconnect structure and alternating with the plurality of the air gap structures. Each of the plurality of the air gap structures includes a dielectric portion and an air gap. The air gap of each of the plurality of the air gap structures is confined by the dielectric portion of the each of the plurality of the air gap structures and two corresponding ones of the plurality of the conductive interconnects.

### BACKGROUND

With rapid development of semiconductor manufacturing technology, continual reduction in minimum feature sizes is a trend in the semiconductor industry. As the feature sizes in an integrated circuit (IC) chip are decreased, the distance between interconnect metal features (e.g., metal lines) is continually reduced in advanced nodes, which might induce resistance-capacitance (RC) delay and electronic signal interference. Therefore, the semiconductor industry strives to reduce the RC delay and the electronic signal interference of the IC chip so as to further improve chip performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 10 are schematic views illustrating some intermediate stages of the method as depicted in FIG. 1 in accordance with some embodiments.

FIG. 11 is a flow diagram illustrating a method for manufacturing a semiconductor device in accordance with some embodiments.

FIGS. 12 to 19 are schematic views illustrating some intermediate stages of the method as depicted in FIG. 11 in accordance with some embodiments.

FIG. 20 is a flow diagram illustrating a method for manufacturing semiconductor device in accordance with some embodiments.

FIGS. 21 to 29 are schematic views illustrating some intermediate stages of the method as depicted in FIG. 20 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “bottom,” “upper,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

With rapid development of semiconductor manufacturing technology, continual reduction in minimum feature sizes is a trend in the semiconductor industry. As the feature sizes in an integrated circuit (IC) chip are decreased, the distance between interconnect metal features (e.g., metal lines) is continually reduced in advanced nodes, and the resulting parasitic capacitance between the interconnect metal features increases, leading to higher power consumption and larger resistance-capacitance (RC) delay for the IC chip. In addition, as the feature sizes in the IC chip are scaled down, difficulty of a manufacturing process for a semiconductor device is also increased (e.g., depositing a metal material layer to fill a plurality of trenches that are formed by patterning an inter-layer dielectric (ILD) layer, so as to form a plurality of metal lines). In order to reduce the difficulty of the metal material layer filling the trenches, a metal reactive ion etching (RIE) process has been developed to form the metal lines. In a current manufacturing process for the semiconductor device, after formation of the metal lines using the metal RIE process, a dielectric material layer is deposited by chemical vapor deposition (CVD) to fill a trench located between two adjacent ones of the metal lines. Because the trench has a small critical dimension, the dielectric material layer may not fully fill the trench, resulting in an air gap being formed in the trench. The air gap has a relatively low dielectric constant (k), which is conducive for reducing the RC delay and the electronic signal interference of the semiconductor device. However, because filling of the dielectric material layer in the trench may be affected by the critical dimension of the trench and various patterning density and topography of the ILD layer, size and height of the air gap are difficult to be controlled, such that the air gap exhibits a non-uniform shape, which is not advantageous for reducing the RC delay and the electronic signal interference of the semiconductor device.

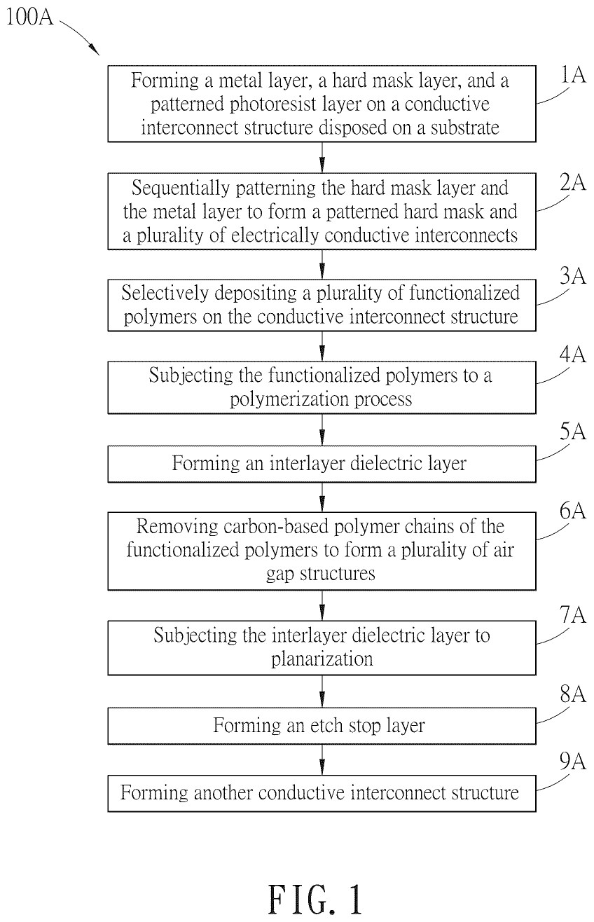

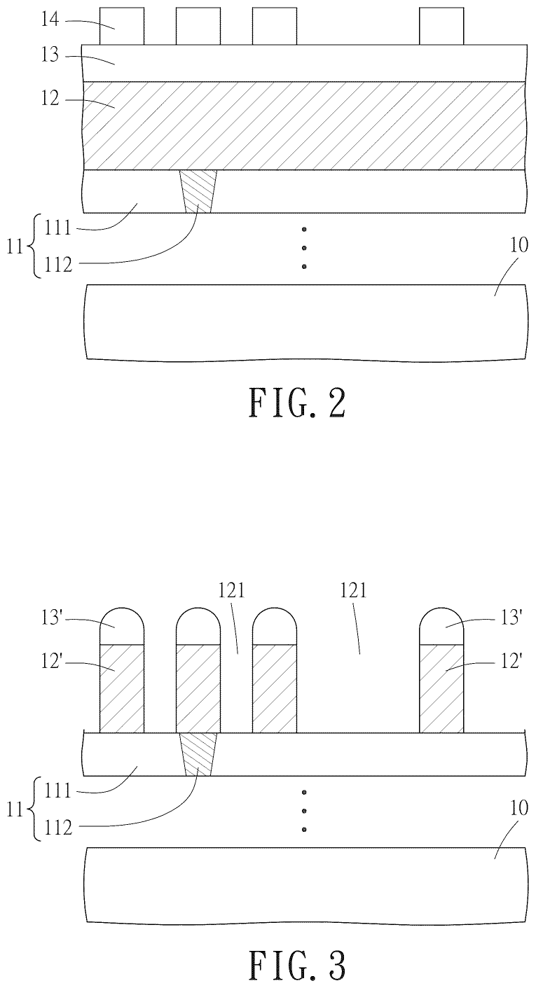

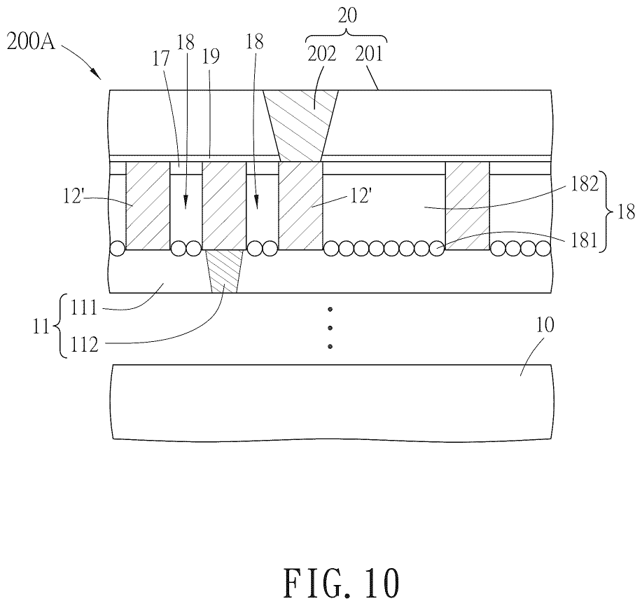

The present disclosure is directed to a semiconductor device formed with air gap structures and a method for manufacturing the same. FIG. 1 is a flow diagram illustrating a method 100A for manufacturing a semiconductor device (for example, a semiconductor device 200A shown in FIG. 10) in accordance with some embodiments. FIGS. 2 to 9 illustrate schematic views of some intermediate stages of the method 100A. Some portions may be omitted in FIGS. 2 to 10 for the sake of brevity. Additional steps can be provided before, after or during the method 100A, and some of the steps described herein may be replaced by other steps or be eliminated.

Referring to FIGS. 1 and 2, the method 100A begins at step 1A, where a metal layer 12, a hard mask layer 13, and a patterned photoresist layer 14 are sequentially formed on a conductive interconnect structure 11 disposed on a substrate 10.

In some embodiments, the substrate 10 may be a semiconductor substrate, e.g., an elemental semiconductor or a compound semiconductor. An elemental semiconductor is composed of single species of atoms, such as silicon (Si) or germanium (Ge) in column IV of the periodic table. A compound semiconductor is composed of two or more elements, such as silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or the like. The compound semiconductor may have a gradient feature in which the composition thereof changes from one ratio at one location to another ratio at another location in the compound semiconductor. The compound semiconductor may be formed over a silicon substrate. The compound semiconductor may be strained. In some embodiments, the substrate 10 may include a multilayer compound semiconductor device. Alternatively, the substrate 10 may include a non-semiconductor material, such as a glass, fused quartz, or calcium fluoride. In some embodiments, the substrate 10 may be a semiconductor on insulator (SOI) (e.g., silicon germanium on insulator (SGOI)). Generally, an SOI substrate includes a layer of a semiconductor material such as epitaxial silicon (Si), germanium (Ge), silicon germanium (SiGe), or combinations thereof. In some embodiments, the substrate 10 may be doped with a p-type dopant, such as boron (Br), aluminum (Al), gallium (Ga), or the like, or may alternatively be doped with an n-type dopant, such as phosphorus (P) or the like.

The conductive interconnect structure 11 is formed on the substrate 10. In some embodiments, the conductive interconnect structure 11 may include a dielectric layer 111 and an electrically conductive interconnect 112 (e.g., an electrically conductive via contact) formed in the dielectric layer 111. The dielectric layer 111 may be made of a dielectric material, for example, but not limited to, silicon oxide, SiOC-based materials (e.g., SiOCH), borophosphosilicate glass (BPSG), undoped silicate glass (USG), fluorinated silicate glass (FSG), high-density plasma (HDP) oxide, fluorine-doped silicon oxide, carbon-doped silicon oxide, porous silicon oxide, porous carbon-doped silicon oxide, organic polymers, or silicone based polymers. Other suitable dielectric materials for the dielectric layer 111 are within the contemplated scope of the present disclosure. The dielectric layer 111 may be formed on the substrate 10 by a suitable deposition process, for example, but not limited to, chemical vapor deposition (CVD), physical vapor deposition (PVD), atomic layer deposition (ALD), or other suitable deposition processes. In some embodiments, the dielectric layer 111 is formed with an opening (not shown). The electrically conductive interconnect 112 is formed in the opening of the dielectric layer 111. The step for forming the electrically conductive interconnect 112 may include sub-step (i) forming an electrically conductive material layer on the dielectric layer 111 and in the opening of the dielectric layer 111, and sub-step (ii) conducting a planarization process (for example, but not limited to, chemical mechanical planarization (CMP)) to remove the electrically conductive material layer on the dielectric layer 111, so as to form the electrically conductive interconnect 112 in the opening of the dielectric layer 111. The electrically conductive material layer may include, for example, but not limited to, copper (Cu), cobalt (Co), ruthenium (Ru), molybdenum (Mo), chromium (Cr), tungsten (W), rhodium (Rh), iridium (Ir), palladium (Pd), platinum (Pt), aluminum (Al), osmium (Os), niobium (Nb), rhenium (Re), vanadium (V), tantalum (Ta), or alloys thereof. In some embodiments, the electrically conductive material layer may include, for example, but not limited to, metal nitride (e.g., tantalum nitride, titanium nitride, or the like). Other suitable materials for the electrically conductive interconnect 112 are within the contemplated scope of the present disclosure. The electrically conductive material layer may be formed by a suitable deposition process, for example, but not limited to, CVD, PVD, ALD, electroless plating, electroplating, or other suitable deposition processes. In some embodiments, the conductive interconnect structure 11 may include a plurality of the electrically conductive interconnects 112.

The metal layer 12 is formed on the conductive interconnect structure 11 opposite to the substrate 10. The metal layer 12 may be made of an electrically conductive material or a low electrical resistance material. The electrically conductive material (or the low electrical resistance material) may include, for example, but not limited to, Cu, Co, Ru, Mo, Cr, W, Rh, Ir, Pd, Pt, Al, Os, Nb, Re, V, Ta, or alloys thereof. In some embodiments, the electrically conductive material (or the low electrical resistance material) may include, for example, but not limited to, metal nitride (e.g., tantalum nitride, titanium nitride, or the like). Other suitable materials for the metal layer 12 are within the contemplated scope of the present disclosure. The metal layer 12 may be formed by a suitable deposition process, for example, but not limited to, PVD, ALD, or other suitable deposition processes. In some embodiments, process parameters for depositing the metal layer 12 may include a temperature that ranges from about 10° C. to about 450° C. In some embodiments, the metal layer 12 may have a thickness ranging from about 200 Å to about 500 Å, and other ranges of the thickness value are also within the contemplated scope of the present disclosure.

The hard mask layer 13 is formed on the metal layer 12 opposite to the conductive interconnect structure 11. The hard mask layer 13 may include a hard mask material having a high etchant resistance with respect to the metal layer 12. In some embodiments, the hard mask layer 13 may include silicon oxide, silicon nitride, silicon carbide, silicon oxycarbide, silicon oxynitride, silicon carbonitride, silicon oxycarbonitride, titanium (Ti), tantalum (Ta), aluminum oxide, or combinations thereof. Other suitable materials for the hard mask layer 13 are within the contemplated scope of the present disclosure. The hard mask layer 13 may be formed by a suitable deposition process, for example, but not limited to, CVD, PVD, ALD, or other suitable deposition processes. In some embodiments, process parameters for depositing the hard mask layer 13 may include a temperature that ranges from about 10° C. to about 400° C. In some embodiments, a ratio of a thickness of the hard mask layer 13 to the thickness of the metal layer 12 may range from about 20% to about 50%, and other ranges of the ratio also within the contemplated scope of the present disclosure. The metal layer 12 has a relatively high etching selectivity with respect to the hard mask layer 13. In some embodiments, an etching selectivity of the metal layer 12 with respect to the hard mask layer 13 may be greater than about 8.

The patterned photoresist layer 14 is formed on the hard mask layer 13 opposite to the metal layer 12. The step for forming the patterned photoresist layer 14 may include sub-step (i) forming a photoresist material layer on the hard mask layer 13, and sub-step (ii) conducting a photolithography process to pattern the photoresist material layer, so as to obtain the patterned photoresist layer 14. The photoresist material layer may be formed by a suitable deposition process, for example, but not limited to, spin-on coating or other suitable deposition processes.

Referring to FIGS. 1 and 3, the method 100A then proceeds to step 2A, where the hard mask layer 13 and the metal layer 12 are sequentially patterned to form a patterned hard mask 13′ and a plurality of electrically conductive interconnects (e.g., metal lines) 12′. Step 2A may include sub-steps (i) and (ii). In sub-step (i), the hard mask layer 13 of the structure shown in FIG. 2 may be etched to form the patterned hard mask 13′. In this sub-step, the patterned photoresist layer 14 is used as a patterned mask. In sub-step (ii), the metal layer 12 of the structure shown in FIG. 2 may be patterned by the RIE process with parameters to form the electrically conductive interconnects 12′ that are disposed on the conductive interconnect structure 11 and that are spaced apart from each other. A plurality of trenches 121 are formed among the electrically conductive interconnects 12′ such that two adjacent ones of the electrically conductive interconnects 12′ are spaced apart from each other by a corresponding one of the trenches 121. In this sub-step, the patterned hard mask 13′ is used as a patterned mask in the RIE process. In some embodiments, the RIE process may be an inductively coupled plasma (ICP) RIE process. In some embodiments, the gas used in the ICP RIE process may be, for example, but not limited to, hydrogen bromide (HBr), chlorine (Cl₂), hydrogen (H₂), methane (CH₄), nitrogen (N₂), helium (He), neon (Ne), krypton (Kr), tetrafluoromethane (CF₄), trifluoromethane (CHF₃), methyl fluoride (CH₃F), difluoromethane (CH₂F₂), octafluorocyclobutane (C₄F₈), hexafluorobutadiene (C₄F₆), oxygen (O₂), argon (Ar), or other suitable gases. In some embodiments, the parameters of the ICP RIE process may include a power that ranges from about 100 watt (W) to about 2000 W. In some embodiments, the parameters of the ICP RIE process may include a bias that ranges from about 0 voltage (V) to about 1200 V. The patterned photoresist layer 14 is removed by, for example, but not limited to, an ashing process or other suitable removal processes after the electrically conductive interconnects 12′ are formed.

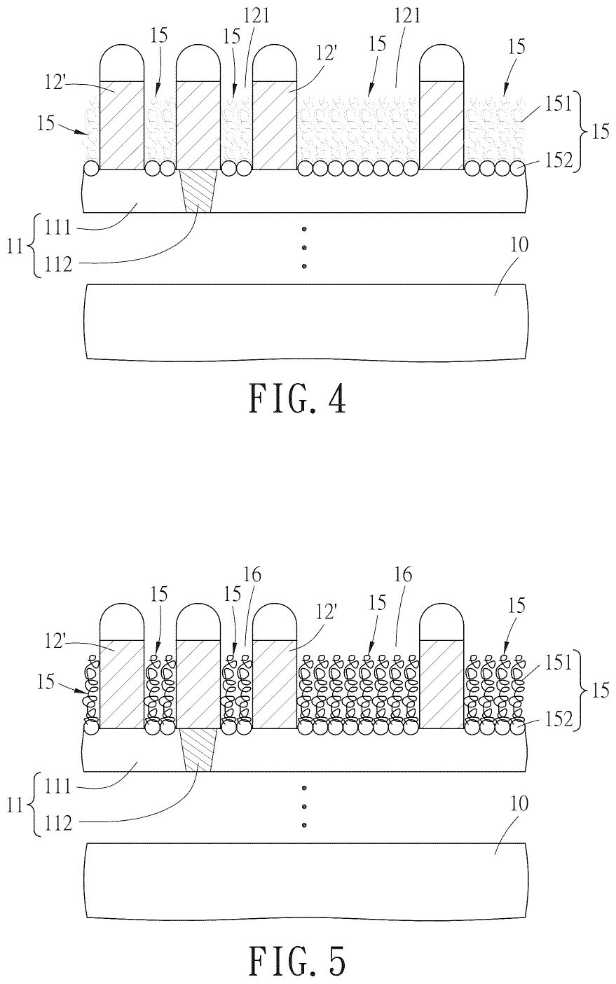

Referring to FIGS. 1 and 4, the method 100A then proceeds to step 3A, where a plurality of functionalized polymers 15 are selectively deposited on an upper surface of the dielectric layer 111 exposed through the trenches 121 (see FIG. 3). Each of the functionalized polymers 15 may include a carbon-based polymer chain 151 and a functional group 152 that can be bonded to the upper surface of the dielectric layer 111 exposed through the trenches 121. In some embodiments, the carbon-based polymer chain 151 may be a polymer chain of a suitable polymer, which may include, for example, but not limited to, polymethyl methacrylate (PMMA), polypropylene (PP), polyethylene (PE), epoxy, copolymers thereof, or other suitable polymers. In some embodiments, the carbon-based polymer chain 151 may have a molecular weight ranging from about 2000 to about 200000. If the molecular weight of the carbon-based polymer chain 151 is less than about 2000, the carbon-based polymer chain 151 may have a short chain length, which may result in an air gap structure 18 (will be described hereinafter with reference to, for example, FIG. 7) to be formed having a relatively small size. If the molecular weight of the carbon-based polymer chain 151 is greater than about 200000, the functionalized polymers 15 may have a relatively high viscosity and the functional group 152 may be covered by the carbon-based polymer chain 151, such that the functional group 152 may not be bonded to the upper surface of the dielectric layer 111 exposed through the trenches 121. In some embodiments, the functional group 152 may be a terminal group that is bonded to the carbon-based polymer chain 151. In some embodiments, the functional group 152 may be an epoxy terminal group, a thiol (—SH) terminal group, an amino (—NH₂) terminal group, a carboxyl (—COOH) terminal group, or a silane-based terminal group represented by Formula A,

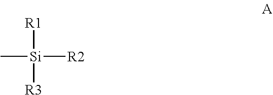

wherein
each of R1, R2, and R3 is a methoxy group (—OCH₃), an ethoxy group (—OC₂H₅), or a propoxy group (—OC₃H₇), and R1, R2, and R3 are the same as or different from each other.

In some embodiments, the functionalized polymers 15 are selectively bonded to the upper surface of the dielectric layer 111 exposed through the trenches 121 by a bonding reaction between the functional group 152 of each of the functionalized polymers 15 and a corresponding one of hydroxyl (—OH) groups formed on the upper surface of the dielectric layer 111 exposed through the trenches 121.

In some embodiments, step 3A may be performed by immersing the structure shown in FIG. 3 in a solution that contains the functionalized polymers 15 and a solvent for dispersing the functionalized polymers 15. In some embodiments, the functionalized polymers 15 may have a concentration ranging from about 30% to about 70% in the solution. When the concentration of the functionalized polymers 15 is lower than about 30% in the solution, step 3A may be required to be performed for a longer reaction period, so as to enable the functional groups 152 of the functionalized polymers 15 to be reacted with the hydroxyl groups on the upper surface of the dielectric layer 111 exposed through the trenches 121. When the concentration of the functionalized polymers 15 is greater than about 70% in the solution, the carbon-based polymer chains 151 of the functionalized polymers 15 may crosslink with each other to an undesirable extent, resulting in a higher viscosity of the solution which inhibits the reaction between the functional groups 152 of the functionalized polymers 15 and the hydroxyl groups of the upper surface of the dielectric layer 111 exposed through the trenches 121. In some embodiments, the solvent may be, for example, but not limited to, tetrahydrofuran (THF), dimethylacetamide (DMAC), methanol, acetone, or other suitable solvents. In some embodiments, step 3A may be performed at a reaction temperature ranging from about 0° C. to about 60° C. In some embodiments, step 3A may be performed for a reaction period ranging from about 3 minutes to about 20 minutes. When the reaction period is shorter than about 3 minutes, the functional groups 152 of the functionalized polymers 15 may not be completely reacted with the hydroxyl groups of the upper surface of the dielectric layer 111 exposed through the trenches 121. When the reaction period is longer than about 20 minutes, the carbon-based polymer chains 151 of the functionalized polymers 15 may crosslink with each other to an undesirable extent, which may lead to an increased viscosity of the solution and may adversely affect the reaction between the functional groups 152 of the functionalized polymers 15 and the hydroxyl groups of the upper surface of the dielectric layer 111 exposed through the trenches 121.

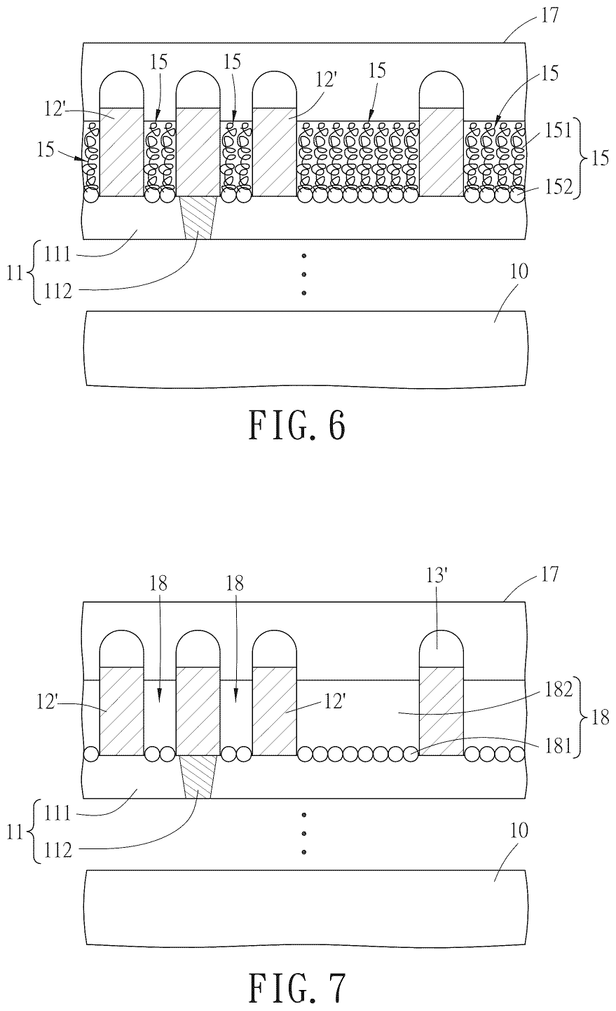

Referring to FIGS. 1 and 5, the method 100A then proceeds to step 4A, where the functionalized polymers 15 undergo a polymerization process to increase a mechanical strength thereof. It is noted that step 4A may be omitted as long as the mechanical strength of the functionalized polymers 15 is sufficient to support an interlayer dielectric (ILD) layer 17 (shown in FIG. 6) that is to be formed in a subsequent step. In some embodiments, each of the functionalized polymers 15 has a length in a vertical direction perpendicular to the substrate 10, each of the electrically conductive interconnects 12′ has a height in the vertical direction, and the length of each of the functionalized polymers 15 is less than the height of each of the electrically conductive interconnects 12′. In some embodiments, when the length of each of the functionalized polymers 15 is greater than the height of each of the electrically conductive interconnects 12′, a dry etching process is conducted, such that the length of each of the functionalized polymers 15 is decreased to be less than the height of each of the electrically conductive interconnects 12′ and such that a plurality of recesses 16 are formed among the electrically conductive interconnects 12′. Each of the recesses 16 is defined by upper portions of two corresponding ones of the electrically conductive interconnects 12′ and corresponding ones of the functionalized polymers 15.

Referring to FIGS. 1 and 6, the method 100A then proceeds to step 5A, where the ILD layer 17 is formed on the structure shown in FIG. 5 and fills the recesses 16. The ILD layer 17 may be made of a low dielectric constant (k) material, for example, but not limited to, aluminum compounds (e.g., aluminum nitride, aluminum oxynitride, aluminum oxide, etc.), silicon compounds (e.g., silicon oxide, silicon oxycarbide, silicon oxynitride, silicon carbonitride, silicon oxycarbonitride, etc.), or combinations thereof. Other suitable low k materials for the ILD layer 17 are within the contemplated scope of the present disclosure. In some embodiments, the ILD layer 17 may be made of the low k material with a porosity ranging from about 20% to about 40%. The ILD layer 17 may be formed by a suitable deposition process, for example, but not limited to, PVD, CVD, ALD, or other suitable deposition processes.

Referring to FIGS. 1 and 7, the method 100A then proceeds to step 6A, where the carbon-based polymer chains 151 of the functionalized polymers 15 in the structure shown in FIG. 6 are removed to form a plurality of the air gap structures 18 among the electrically conductive interconnects 12′ in a self-aligned manner. Step 6A may be performed by a thermal annealing process to permit the carbon-based polymer chains 151 of the functionalized polymers 15 to vaporize through the ILD layer 17 which is porous. In some embodiments, the thermal annealing process may be conducted at a temperature ranging from about 300° C. to about 400° C. When the temperature of the thermal annealing process is lower than about 300° C., the carbon-based polymer chains 151 of the functionalized polymers 15 may not be vaporized completely, which is not conducive to forming the air gap structures 18. When the temperature of the thermal annealing process is higher than about 400° C., the ILD layer 17 may be damaged. As described above with reference to step 5A, the ILD layer 17 may have a porosity ranging from about 20% to about 40%. When the porosity of the ILD layer 17 is lower than about 20%, the carbon-based polymer chains 151 of the functionalized polymers 15 may not be removed effectively through pores of the ILD layer 17 during the thermal annealing process, and some ash may remain in the air gap structures 18, which may affect the size of the air gap structures 18. When the porosity of the ILD layer 17 is greater than about 40%, the ILD layer 17 may have a poor mechanical strength. Two adjacent ones of the electrically conductive interconnects 12′ may be spaced apart from each other by a corresponding one of the air gap structures 18. Each of the air gap structures 18 includes a bottom layer (a dielectric portion) 181 formed by the functional groups 152 of the functionalized polymers 15, and an air gap 182 defined by two corresponding ones of the electrically conductive interconnects 12′, a corresponding portion of the ILD layer 17, and the bottom layer 181.

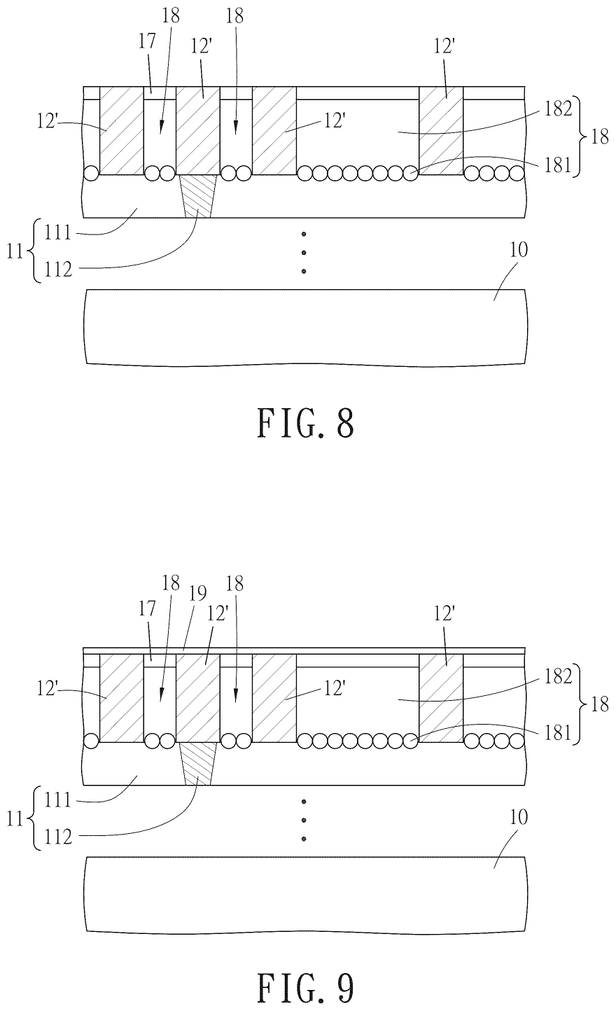

Referring to FIGS. 1 and 8, the method 100 then proceeds to step 7A, where the ILD layer 17 of the structure shown in FIG. 7 is planarized to expose upper surfaces of the electrically conductive interconnects 12′. Step 7A may be performed by a suitable planarization process, for example, but not limited to, CMP or other suitable planarization processes. In this step, the patterned hard mask 13′ shown in FIG. 7 is fully removed.

Referring to FIGS. 1 and 9, the method 100A then proceeds to step 8A, where an etch stop layer (ESL) 19 is formed on the structure shown in FIG. 8. In some embodiments, the ESL 19 may include, for example, but not limited to, aluminum compounds (e.g., aluminum nitride, aluminum oxynitride, aluminum oxide, etc.), silicon compounds (e.g., silicon oxide, silicon nitride, silicon carbide, silicon oxycarbide, silicon oxynitride, silicon carbonitride, silicon oxycarbonitride, etc.), or combinations thereof. Other suitable materials for the ESL 19 are within the contemplated scope of the present disclosure. The ESL 19 may be formed by a suitable deposition process, for example, but not limited to, CVD, PVD, ALD, PECVD, PEALD, spin-on coating, or other suitable deposition processes. In some embodiments, the deposition process may be conducted at a temperature ranging from about 20° C. to about 400° C. In some embodiments, the ESL 18 has a thickness ranging from about 10 Å to about 300 Å.

Referring to FIGS. 1 and 10, the method 100A then proceeds to step 9A, where a conductive interconnect structure 20 is formed. The semiconductor device 200A is obtained accordingly. The conductive interconnect structure 20 may include a dielectric layer 201 and an electrically conductive interconnect 202 (e.g., an electrically conductive via contact). The dielectric layer 201 of the conductive interconnect structure 20 is formed on the ESL 19. The material and process for forming the dielectric layer 201 of the conductive interconnect structure 20 are similar to those of the dielectric layer 111 as described in step 1A, and thus, the details thereof are omitted for the sake of brevity. The electrically conductive interconnect 202 of the conductive interconnect structure 20 penetrates the ESL 19 and is disposed on and electrically connected to a corresponding one of the electrically conductive interconnects 12′. The material and process for forming the electrically conductive interconnect 202 are similar to those of the electrically conductive interconnect 112 as described in step 1A, and thus, the details thereof are omitted for the sake of brevity. The conductive interconnect structure 20 may be formed by a damascene process or the RIE process.

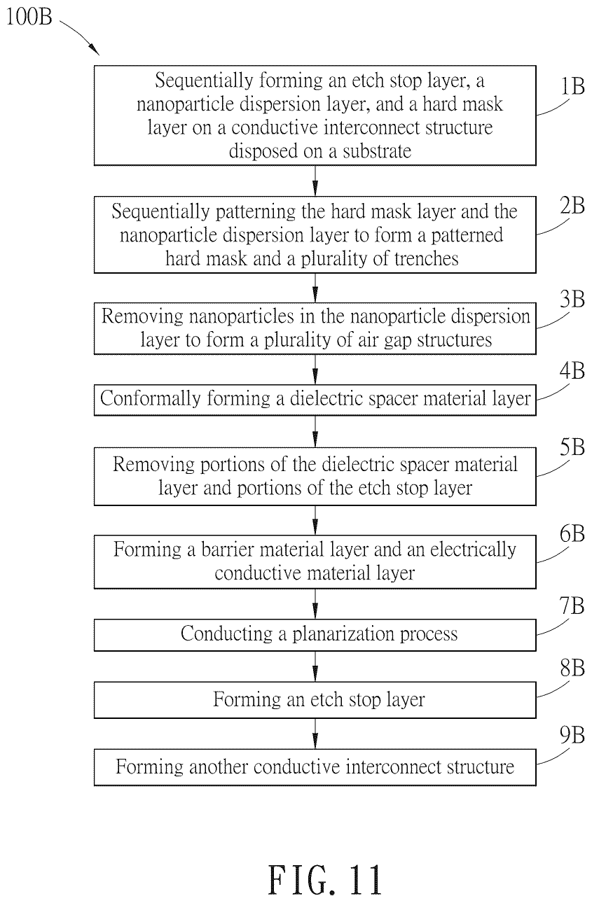

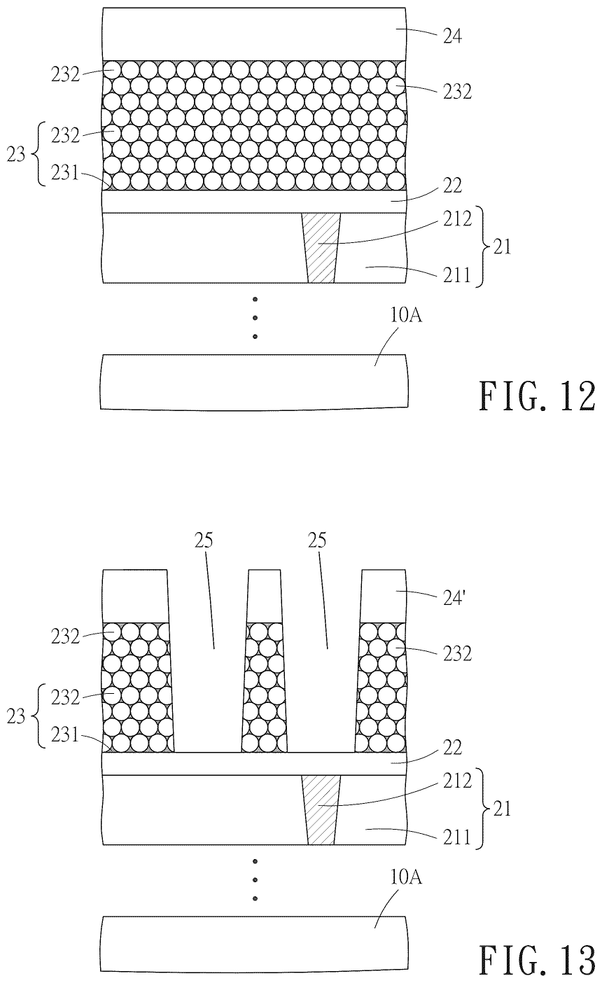

FIG. 11 is a flow diagram illustrating a method 100B for manufacturing a semiconductor device (for example, a semiconductor device 200B shown in FIG. 19) in accordance with some embodiments. FIGS. 12 to 18 illustrate schematic views of some intermediate stages of the method 100B. Some portions may be omitted in FIGS. 12 to 19 for the sake of brevity. Additional steps can be provided before, after or during the method 100B, and some of the steps described herein may be replaced by other steps or be eliminated.

Referring to FIGS. 11 and 12, the method 100B begins at step 1B, where an etch stop layer (ESL) 22, a nanoparticle dispersion layer 23, and a hard mask layer 24 are sequentially formed on a conductive interconnect structure 21 disposed on a substrate 10A.

In some embodiments, the substrate 10A is a semiconductor substrate, which is the same as or similar to that described above for the substrate 10 in step 1A, and thus details thereof are omitted for the sake of brevity.

The conductive interconnect structure 21 may include a dielectric layer 211 and an electrically conductive interconnect 212 (e.g., an electrically conductive via contact) formed in the dielectric layer 211. The material and process for forming the dielectric layer 211 may be the same as or similar to those for forming the dielectric layer 111 as described in step 1A, and thus, the details thereof are omitted for the sake of brevity. In addition, the material and process for forming the electrically conductive interconnect 212 may be the same as or similar to those for forming the electrically conductive interconnect 112 as described in step 1A, and thus, the details thereof are omitted for the sake of brevity.

The ESL 22 is formed on the conductive interconnect structure 21 opposite to the substrate 10A. The material and process for forming the ESL 22 may be the same as or similar to those for forming the ESL 19 as described in step 8A, and thus, the details thereof are omitted for the sake of brevity.

The nanoparticle dispersion layer 23 is formed on the ESL 22 opposite to the conductive interconnect structure 21. In some embodiments, the nanoparticle dispersion layer 23 has a thickness ranging from about 50 Å to about 1000 Å. The nanoparticle dispersion layer 23 includes a dielectric layer 231 and a plurality of nanoparticles 232, which are dispersed in the dielectric layer 231 and which are in contact with each other. In some embodiments, a concentration of the nanoparticles 232 in the nanoparticle dispersion layer 23 ranges from about 50 vol % to about 80 vol %. When the concentration of the nanoparticles 232 in the nanoparticle dispersion layer 23 is less than 50 vol %, the nanoparticles 232 may not be in contact with each other. In some embodiments, the dielectric layer 231 includes, for example, but not limited to, silicon oxide, silicon nitride, silicon carbide, silicon oxycarbide, silicon oxynitride, silicon carbonitride, silicon oxycarbonitride, or combinations thereof. Other suitable dielectric materials for the dielectric layer 231 are within the contemplated scope of the present disclosure. In some embodiments, nanoparticles 232 may include, for example, but not limited to, a carbon-based polymer, a dielectric material, or a metal-based material. In some embodiments, the carbon-based polymer may include, for example, but not limited to, polymethyl methacrylate, polyimide, or a combination thereof. In some embodiments, the carbon-based polymer may have a molecular weight ranging from about 2000 to about 20000. In some embodiments, the dielectric material for the nanoparticles 232 may include, for example, but not limited to, silicon oxide, silicon nitride, silicon carbide, silicon oxycarbide, silicon oxynitride, silicon carbonitride, silicon oxycarbonitride, or combinations thereof. When the nanoparticles 232 includes the dielectric material, the dielectric material for the nanoparticles 232 is different from the dielectric material for the dielectric layer 231. In some embodiments, the metal-based material may include, for example, but not limited to, metal (e.g., titanium (Ti), tungsten (W), aluminum (Al), or the like), metal nitride (e.g., titanium nitride, tungsten nitride, aluminum nitride, or the like), metal carbide (e.g., titanium carbide, tungsten carbide, aluminum carbide, or the like), or metal oxide (e.g., titanium oxide, tungsten oxide, aluminum oxide, or the like). Other suitable materials for the nanoparticles 232 are within the contemplated scope of the present disclosure. In some embodiments, each of the nanoparticles 232 has a diameter ranging from about 10 Å to about 100 Å. In some embodiments, the nanoparticle dispersion layer 23 may be formed on the ESL 22 by applying a dispersion including the dielectric material for the dielectric layer 231 and the nanoparticles 232 dispersed in the dielectric material using a suitable coating process (for example, but not limited to, a spin-on coating process).

The hard mask layer 24 is formed on the nanoparticle dispersion layer 23 opposite to the ESL 22. In some embodiments, the hard mask layer 24 has a thickness ranging from about 30 Å to about 500 Å. In some embodiments, the hard mask layer 24 may include, for example, but not limited to, silicon oxide, silicon nitride, silicon carbide, silicon oxycarbide, silicon oxynitride, silicon carbonitride, silicon oxycarbonitride, tungsten (W), titanium (Ti), tantalum (Ta), aluminum oxide, aluminum oxynitride, titanium oxide, titanium nitride, tungsten carbide, hafnium oxide, zirconium oxide, zinc oxide, titanium zirconium oxide, or combinations thereof. Other suitable materials for the hard mask layer 24 are within the contemplated scope of the present disclosure. The hard mask layer 24 may be formed by a suitable deposition process, for example, but not limited to, CVD, PVD, ALD, or other suitable deposition processes. In some embodiments, process parameters for depositing the hard mask layer 13 may include a temperature that ranges from about 50° C. to about 400° C.

Referring to FIGS. 11 and 13, the method 100B then proceeds to step 2B, where the hard mask layer 24 and the nanoparticle disposition layer 23 of the structure shown in FIG. 12 are sequentially patterned to form a patterned hard mask 24′ and a plurality of trenches 25. Step 2B may include sub-steps (i) and (ii). In sub-step (i), the hard mask layer 24 may be etched to form the patterned hard mask 24′. In this sub-step, a patterned photoresist layer (not shown) disposed on the hard mask layer 24 is used as a patterned mask. In sub-step (ii), the nanoparticle dispersion layer 23 is patterned by a suitable etching process (for example, a wet etching process, a dry etching process, or a combination thereof) to form the trenches 25 in the nanoparticle dispersion layer 23 so as to expose the ESL 22 through the trenches 25. In this sub-step, the patterned hard mask 24′ is used as a patterned mask in the etching process.

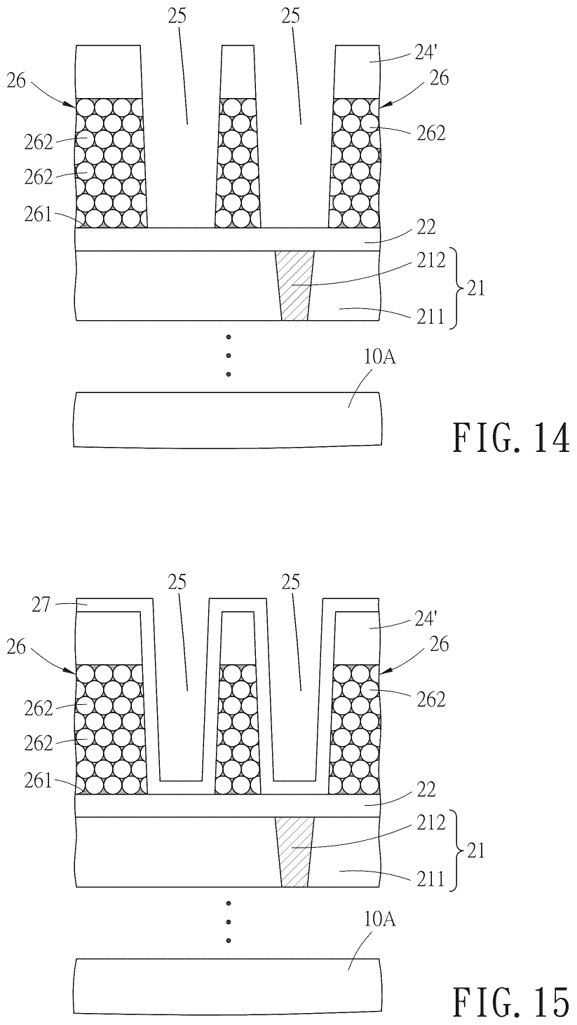

Referring to FIGS. 11 and 14, the method 100B then proceeds to step 3B, where the nanoparticles 232 dispersed in the dielectric layer 231 of the structure shown in FIG. 13 are removed so as to form a plurality of air gap structures 26. Two adjacent ones of the air gap structures 26 are spaced apart from each other by a corresponding one of the trenches 25. Each of the air gap structures 26 includes a dielectric portion 261 extending upwardly from the ESL 22 in a vertical direction perpendicular to the ESL 22, and a plurality of nanopores 262 distributed in the dielectric portion 261 and spatially communicated with each other. In some embodiments, the air gap structures 26 has a porosity ranging from about 50% to about 80%. In some embodiments, each of the nanopores 262 has a diameter ranging from about 10 Å to about 100 Å. In some embodiments, the nanoparticles 232 dispersed in the dielectric layer 231 of the structure shown in FIG. 13 are selectively removed by a suitable selective removal process, for example, but not limited to, a selective etching process, a wet clean removal process, a baking process, or the like. In some embodiments, the selective etching process includes, for example, but not limited to, an inductively coupled plasma (ICP) process, a capacitively coupled plasma (CCP) process, a remote plasma process, or the like. Other suitable plasma treatment processes are within the contemplated scope of the present disclosure. In some embodiments, an etch gas used for the selective etching process includes, for example, but not limited to, methane (CH₄), fluoromethane (CH₃F), difluoromethane (CH₂F₂), trifluoromethane (CHF₃), octafluorocyclobutane (C₄F₈), hexafluorobutadiene (C₄F₆), tetrafluoromethane (CF₄), nitrogen trifluoride (NF₃), ammonia (NH₃), hydrogen gas (H₂), hydrogen fluoride (HF), hydrogen bromide (HBr), carbon monoxide (CO), carbon dioxide (CO₂), oxygen gas (O₂), boron trichloride (BCl₃), chlorine gas (Cl₂), nitrogen gas (N₂), helium gas (He), neon gas (Ne), argon gas (Ar), or combinations thereof. In some embodiment, the selective etching process may be conducted at a power ranging from about 0 watt (W) to about 3000 W. In some embodiments, the selective etching process may be conducted at a pressure ranging from about 0.2 millitorr (mT) to about 120 mT. In some embodiment, the selective etching process may be conducted at a temperature ranging from about 0° C. to about 180° C. In some embodiment, the selective etching process may be conducted at a bias ranging from about 0 voltage (V) to about 1200 V. In some embodiments, the baking process may be conducted at a temperature ranging from about 100° C. to about 450° C.

Referring to FIGS. 11 and 15, the method 100B then proceeds to step 4B, where a dielectric spacer material layer 27 is conformally formed on the structure shown in FIG. 14 to cover the patterned hard mask 24′, the air gap structures 26, and portions of the ESL 22 exposed through the trenches 25. In some embodiments, the dielectric spacer material layer 27 may include, for example, but not limited to, silicon oxide, silicon nitride, silicon carbide, silicon oxycarbide, silicon oxynitride, silicon carbonitride, silicon oxycarbonitride, or combinations thereof. Other suitable materials for the dielectric spacer material layer 27 are within the contemplated scope of the present disclosure. The material for the dielectric spacer material layer 27 may be the same as or different from that for the dielectric portion 261. The dielectric spacer material layer 27 may be formed by a suitable deposition process, for example, but not limited to, CVD, PVD, ALD, a spin-on coating process, or other suitable deposition processes.

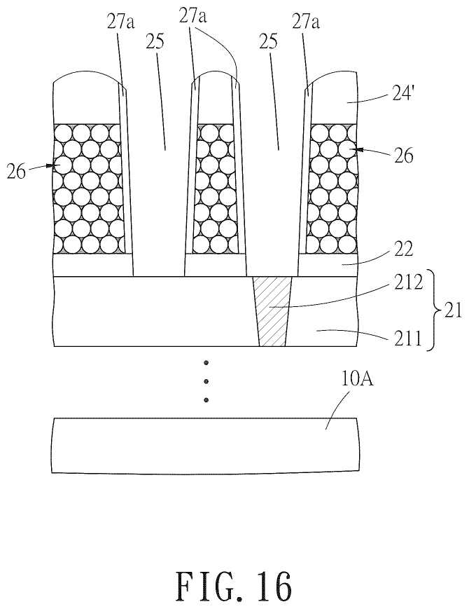

Referring to FIGS. 11 and 16, the method 100B then proceeds to step 5B, where portions of the dielectric spacer material layer 27 and portions of the ESL 22 of the structure shown in FIG. 15 are removed. Portions of the dielectric spacer material layer 27 disposed on an upper surface of the patterned mask layer 24′ and portions of the dielectric spacer material layer 27 disposed on the ESL 22 are removed by a suitable removal process, for example, but not limited to, the selective etching process or the wet clean removal process for removing the nanoparticles 232 dispersed in the dielectric layer 231 as described above, and thus the details thereof are omitted for the sake of brevity. Portions of the ESL 22, which are exposed through the trenches 25 after the portions of the dielectric spacer material layer 27 disposed on the ESL 22 are removed, are removed by a suitable removal process, for example, but not limited to, the selective etching process or the wet clean removal process for removing the nanoparticles 232 dispersed in the dielectric layer 231 as described above, and thus the details thereof are omitted for the sake of brevity. A plurality of dielectric spacers 27a are formed accordingly. Each of the air gap structures 26 are laterally covered by two corresponding ones of the dielectric spacers 27a disposed oppositely with respect to the each of the air gap structures 26.

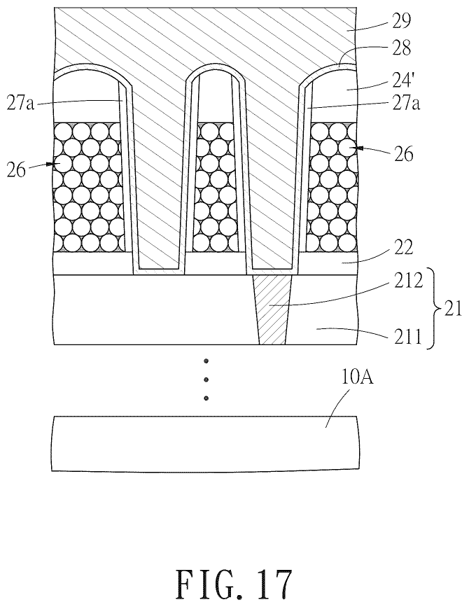

Referring to FIGS. 11 and 17, the method 100B then proceeds to step 6B, where a barrier material layer 28 and an electrically conductive material layer 29 are formed. The barrier material layer 28 is conformally deposited on the structure shown in FIG. 16. In some embodiments, the barrier material layer 28 may include, for example, but not limited to, metal (e.g., ruthenium (Ru), manganese (Mn), cobalt (Co), chromium (Cr), tantalum (Ta), or the like), metal nitride (e.g., titanium nitride, tantalum nitride, tungsten nitride, or the like), metal carbide (e.g., titanium carbide, tantalum carbide, tungsten carbide, or the like), metal oxide (e.g., titanium oxide, tantalum oxide, tungsten oxide, or the like), or combinations thereof. Other suitable materials for the barrier material layer 28 are within the contemplated scope of the present disclosure. In some embodiments, the barrier material layer 28 has a thickness ranging from about 5 Å to about 200 Å. In some embodiments, the barrier material layer 28 may be formed by a suitable conformal deposition process, for example, but not limited to, CVD, PVD, ALD, or other suitable deposition processes. The electrically conductive material layer 29 is then formed on the barrier material layer 28 so as to permit the trenches 25 (see FIG. 16) to be filled with the electrically conductive material layer 29. In some embodiments, the electrically conductive material layer 29 may include, for example, copper (Cu), aluminum (Al), gold (Au), silver (Ag), tungsten (W), cobalt (Co), ruthenium (Ru), molybdenum (Mo), chromium (Cr), manganese (Mn), rhodium (Rh), iridium (Ir), nickel (Ni), palladium (Pd), platinum (Pt), tantalum (Ta), or alloys thereof. In some embodiments, the electrically conductive material layer 29 may include, for example, but not limited to, metal nitride (e.g., tantalum nitride, titanium nitride, or the like). In some embodiments, the electrically conductive material layer 29 may be formed by a suitable process, for example, but not limited to, electroless plating, electroplating, sputter deposition, or CVD.

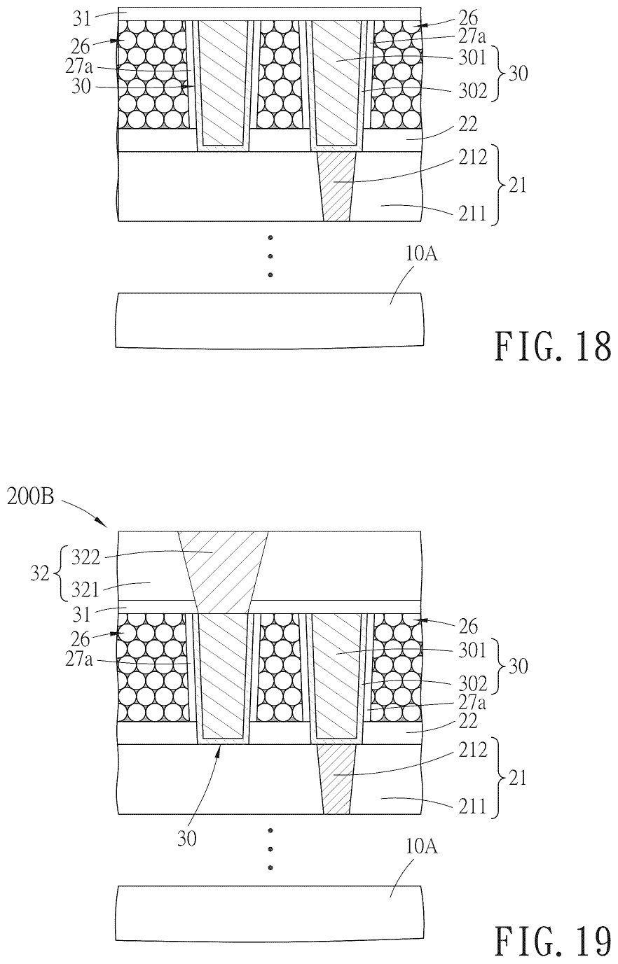

Referring to FIGS. 11 and 18, the method 100B then proceeds to step 7B, where a planarization process is conducted. The planarization process (for example, but not limited to, CMP) is conducted to remove an upper portion of the electrically conductive material layer 29, upper portions of the barrier material layer 28, upper portions of the dielectric spacers 27a, and the patterned hard mask 24′ of the structure shown in FIG. 17, so as to form a plurality of electrically conductive interconnects (e.g., metal lines) 30. Two adjacent ones of the electrically conductive interconnects 30 are spaced apart from each other by a corresponding one of the air gap structures 26. One of the electrically conductive interconnects 30 penetrate the ESL 22 so as to be connected to the electrically conductive interconnect 212 of the conductive interconnect structure 21. Each of the electrically conductive interconnects 30 includes a bulk metal portion 301 and a barrier layer 302 which covers a lateral surface and a bottom surface of the bulk metal portion 301. Each of the dielectric spacers 27a extends upwardly from the ESL 22 in the vertical direction and laterally covers a corresponding one of the air gap structures 26, so as to permit the corresponding one of the air gap structures 26 to be spaced apart from a corresponding one of the electrically conductive interconnects 30 by the each of the dielectric spacers 27a.

Referring to FIGS. 11 and 18, the method 100B then proceeds to step 8B, where an ESL 31 is formed on the air gap structures 26 and the electrically conductive interconnects 30. The material and process for forming the ESL 31 may be the same as or similar to those for forming the ESL 19 as described in step 8A, and thus, the details thereof are omitted for the sake of brevity.

Referring to FIGS. 11 and 19, the method 100B then proceeds to step 9B, where a conductive interconnect structure 32 is formed. The conductive interconnect structure 32 may include a dielectric layer 321 and an electrically conductive interconnect 322 (e.g., an electrically conductive via contact). The dielectric layer 321 of the conductive interconnect structure 32 is formed on the ESL 31. The material and process for forming the dielectric layer 321 of the conductive interconnect structure 32 are similar to those of the dielectric layer 111 as described in step 1A, and thus, the details thereof are omitted for the sake of brevity. The electrically conductive interconnect 322 of the conductive interconnect structure 32 penetrates the ESL 31 and is disposed on and electrically connected to a corresponding one of the electrically conductive interconnects 30. The material and process for forming the electrically conductive interconnect 322 are similar to those of the electrically conductive interconnect 112 as described in step 1A, and thus, the details thereof are omitted for the sake of brevity. The conductive interconnect structure 32 may be formed by a damascene process or the RIE process.

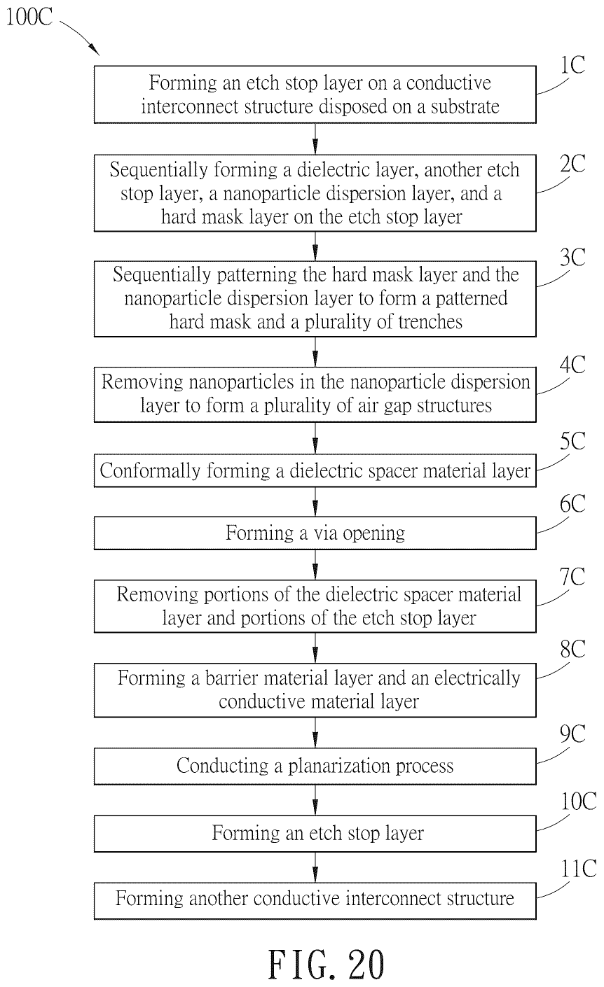

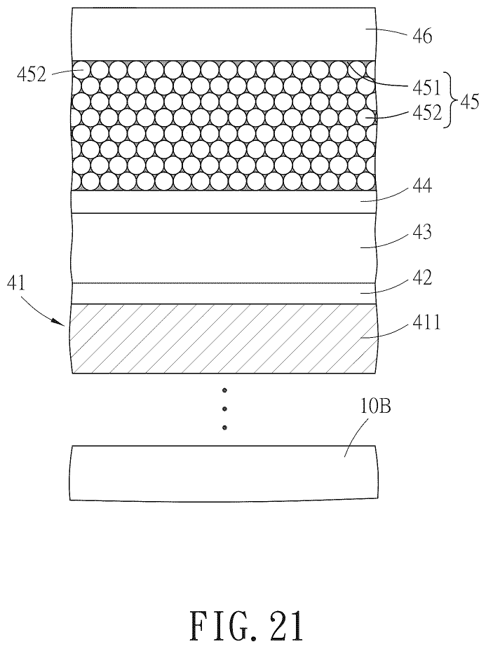

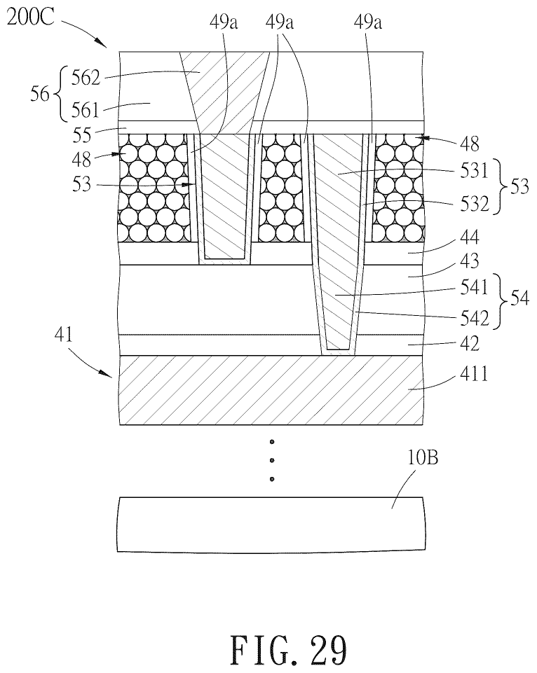

FIG. 20 is a flow diagram illustrating a method 100C for manufacturing a semiconductor device (for example, a semiconductor device 200C shown in FIG. 29) in accordance with some embodiments. FIGS. 21 to 28 illustrate schematic views of some intermediate stages of the method 100C. Some portions may be omitted in FIGS. 21 to 29 for the sake of brevity. Additional steps can be provided before, after or during the method 100C, and some of the steps described herein may be replaced by other steps or be eliminated.

Referring to FIGS. 20 and 21, the method 100C begins at step 1C, where an etch stop layer (ESL) 42 is formed on a conductive interconnect structure 41 disposed on a substrate 10B.

In some embodiments, the substrate 10B is a semiconductor substrate, which is the same as or similar to that described above for the substrate 10 in step 1A, and thus details thereof are omitted for the sake of brevity.

The conductive interconnect structure 41 may include a dielectric layer (not shown) and a plurality of electrically conductive interconnects 411 (e.g., metal lines) formed in the dielectric layer and spaced part from each other. The material and process for forming the dielectric layer may be the same as or similar to those for forming the dielectric layer 111 as described in step 1A, and thus, the details thereof are omitted for the sake of brevity. In addition, the material and process for forming the electrically conductive interconnects 411 may be the same as or similar to those for forming the electrically conductive interconnect 112 as described in step 1A, and thus, the details thereof are omitted for the sake of brevity.

The ESL 42 is formed on the conductive interconnect structure 41 opposite to the substrate 10B. The material and process for forming the ESL 42 may be the same as or similar to those for forming the ESL 19 as described in step 8A, and thus, the details thereof are omitted for the sake of brevity.

Referring to FIGS. 20 and 21, the method 100C then proceeds to step 2C, where a dielectric layer 43, an ESL 44, a nanoparticle dispersion layer 45, and a hard mask layer 46 are sequentially formed on the ESL 42.

The dielectric layer 43 is formed on the ESL layer 42 opposite to the conductive interconnect structure 41. The material and process for forming the dielectric layer 43 are similar to those of the dielectric layer 111 as described in step 1A, and thus, the details thereof are omitted for the sake of brevity.

The ESL 44 is formed on the dielectric layer 43 opposite to the ESL 42. The material and process for forming the ESL 44 may be the same as or similar to those for forming the ESL 19 as described in step 8A, and thus, the details thereof are omitted for the sake of brevity.

The nanoparticle dispersion layer 45 is formed on the ESL 44 opposite to the dielectric layer 43. In some embodiments, the nanoparticle dispersion layer 45 has a thickness ranging from about 50 Å to about 1000 Å. The nanoparticle dispersion layer 45 includes a dielectric layer 451 and a plurality of nanoparticles 452 dispersed in the dielectric layer 451. The materials and processes for forming the nanoparticle dispersion layer 45 may be the same as or similar to those for forming the nanoparticle dispersion layer 23 as described in step 1B, and thus, the details thereof are omitted for the sake of brevity.

The hard mask layer 46 is formed on the nanoparticle dispersion layer 45 opposite to the ESL 44. In some embodiments, the hard mask layer 46 has a thickness ranging from about 30 Å to about 500 Å. The material and process for forming the hard mask layer 46 may be the same as or similar to those for forming the hard mask layer 24 as described in step 1B, and thus, the details thereof are omitted for the sake of brevity.

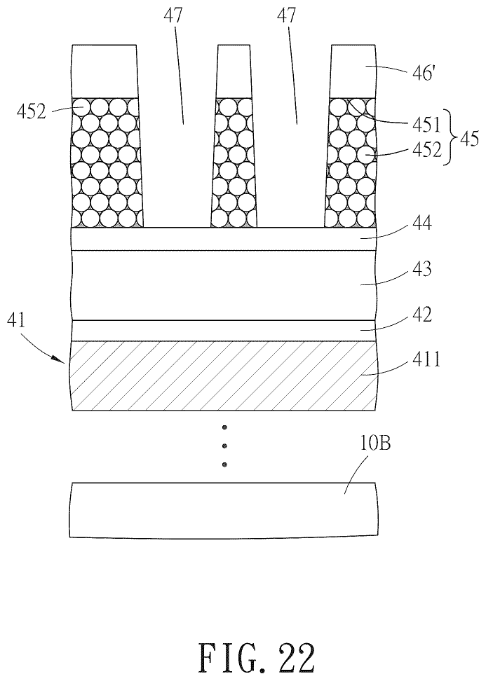

Referring to FIGS. 20 and 22, the method 100C then proceeds to step 3C, where the hard mask layer 46 and the nanoparticle disposition layer 45 of the structure shown in FIG. 21 are sequentially patterned to form a patterned hard mask 46′ and a plurality of trenches 47. The processes for forming the patterned hard mask 46′ and the trenches 47 may be the same as or similar to those for forming the patterned hard mask 24′ and the trenches 25 as described in step 2B, and thus, the details thereof are omitted for the sake of brevity. The ESL 44 serves as an etch stop layer when the hard mask layer 46 and the nanoparticle disposition layer 45 are patterned.

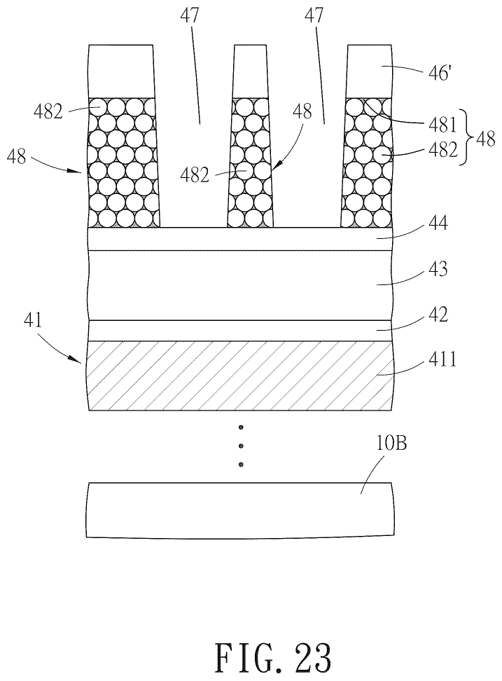

Referring to FIGS. 20 and 23, the method 100C then proceeds to step 4C, where the nanoparticles 452 dispersed in the dielectric layer 451 of the structure shown in FIG. 22 are removed so as to form a plurality of air gap structures 48. Two adjacent ones of the air gap structure 48 are spaced apart from each other by a corresponding one of the trenches 47. Each of the air gap structures 48 includes a dielectric portion 481 extending upwardly from the ESL 44 in a vertical direction perpendicular to the ESL 44, and a plurality of nanopores 482 distributed in the dielectric portion 481 and spatially communicated with each other. In some embodiments, each of the nanopores 482 has a diameter ranging from about 10 Å to about 100 Å. The processes for removing the nanoparticles 452 dispersed in the dielectric layer 451 of the structure shown in FIG. 22 are the same as or similar to those for removing the nanoparticles 232 dispersed in the dielectric layer 231 of the structure shown in FIG. 13 as described in step 3B, and thus the details thereof are omitted for the sake of brevity.

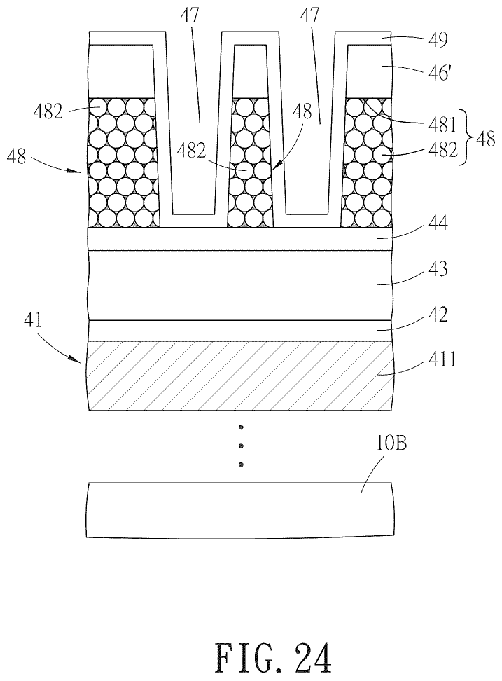

Referring to FIGS. 20 and 24, the method 100C then proceeds to step 5C, where a dielectric spacer material layer 49 is conformally formed on the structure shown in FIG. 23 to cover the patterned hard mask 46′, the air gap structures 48, and portions of the ESL 44 exposed through the trenches 47. The material and process for forming the dielectric spacer material layer 49 may be the same as or similar to those for forming the dielectric spacer material layer 27 as described in step 4B, and thus the details thereof are omitted for the sake of brevity.

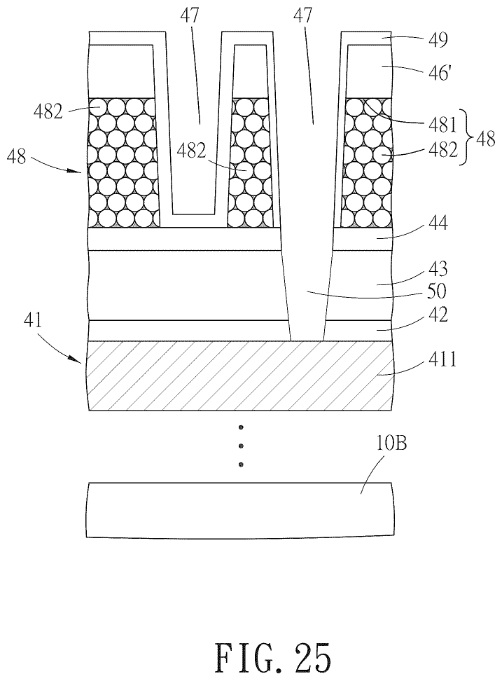

Referring to FIGS. 20 and 25, the method 100C then proceeds to step 6C, where a via opening 50 is formed. The via opening 50 is formed to be disposed below and spatially communicated with a corresponding one of the trenches 47. In some embodiments, the via opening 50 may have a depth ranging from about 30 Å to about 1000 Å. In some embodiments, formation of the via opening 50 may be conducted by a suitable selective etching process, for example, but not limited to, a wet etching process or a dry etching process through a patterned mask layer (not shown) disposed over the structure shown in FIG. 24, so as to remove a bottom portion of the dielectric spacer material layer 49 exposed from the corresponding one of the trenches 47, a portion of the ESL 44 disposed below the bottom portion of the dielectric spacer material layer 49 to be removed, and a portion of the dielectric layer 43 disposed below the portion of the ESL 44 to be removed. In some embodiments, after the via opening 40 is formed, the patterned mask layer may be removed by a suitable removing process, for example, but not limited to, an etching process or an ashing process.

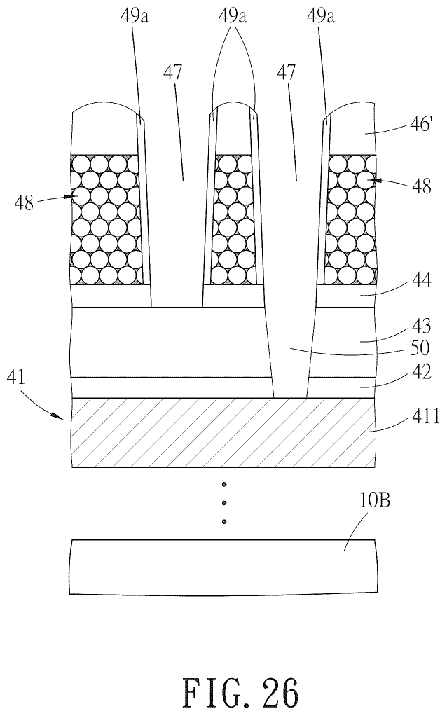

Referring to FIGS. 20 and 26, the method 100C then proceeds to step 7C, where portions of the dielectric spacer material layer 49 and portions of the ESL 44 are removed. Portions of the dielectric spacer material layer 49 disposed on an upper surface of the patterned mask layer 46′ and portions of the dielectric spacer material layer 49 disposed on the ESL 44 are removed by a suitable removal process, which may be the same as or similar to the selective etching process or the wet clean removal process for removing the nanoparticles 232 dispersed in the dielectric layer 231 as described in step 3B, and thus the details thereof are omitted for the sake of brevity. Portions of the ESL 44, which are exposed through the trenches 47 after the portions of the dielectric spacer material layer 49 disposed on the ESL 44 are removed, are removed by a suitable removal process, for example, but not limited to, the selective etching process or the wet clean removal process for removing the nanoparticles 232 dispersed in the dielectric layer 231 as described in step 3B, and thus the details thereof are omitted for the sake of brevity. A plurality of dielectric spacers 49a are formed accordingly. Each of the air gap structures 48 are laterally covered by two corresponding ones of the dielectric spacers 49a disposed oppositely to each other with respect to the each of the air gap structures 48.

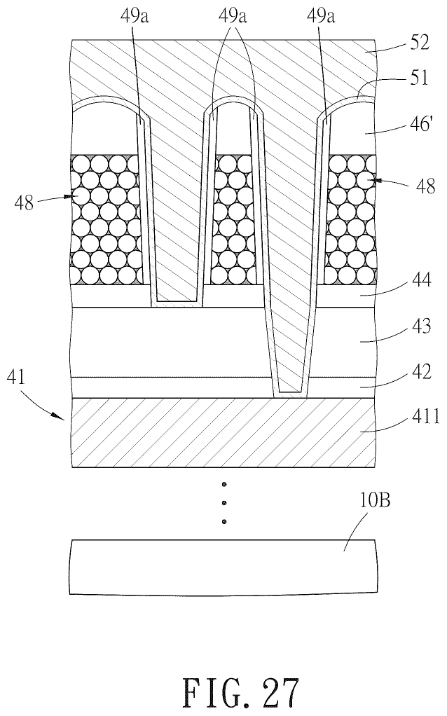

Referring to FIGS. 20 and 27, the method 100C then proceeds to step 8C, where a barrier material layer 51 and an electrically conductive material layer 52 are formed. The barrier material layer 51 is conformally deposited on the structure shown in FIG. 26. The material and process for forming the barrier material layer 51 may be the same as or similar to those for forming the barrier material layer 28 as described in step 6B, and thus the details thereof are omitted for the sake of brevity. In some embodiments, the barrier material layer 51 has a thickness ranging from about 5 Å to about 200 Å. The electrically conductive material layer 52 is then formed on the barrier material layer 51 so as to permit the trenches 47 and the via opening 50 (see FIG. 26) to be filled with the electrically conductive material layer 52. The material and process for forming the electrically conductive material layer 52 may be the same as or similar to those for forming the electrically conductive material layer 29 as described in step 6B, and thus the details thereof are omitted for the sake of brevity.

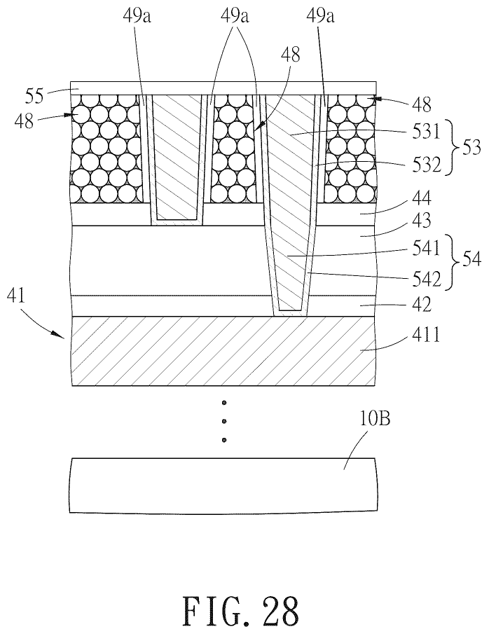

Referring to FIGS. 20 and 28, the method 100C then proceeds to step 9C, where a planarization process is conducted. The planarization process (for example, but not limited to, CMP) is conducted to remove an upper portion of the electrically conductive material layer 52, upper portions of the barrier material layer 51, upper portions of the dielectric spacers 49a, and the patterned hard mask 46′ of the structure shown in FIG. 27, so as to form a plurality of electrically conductive interconnects (e.g., metal lines) 53 and an electrically conductive interconnect (e.g., a via contact) 54. Two adjacent ones of the electrically conductive interconnects 53 are spaced apart from each other by a corresponding one of the air gap structures 48. One of the electrically conductive interconnects 53 penetrate the ESL 44 so as to be connected to the electrically conductive interconnect 54. Each of the electrically conductive interconnect 53 includes a bulk metal portion 531 and a barrier layer 532 which covers a lateral surface of the bulk metal portion 531. Each of the dielectric spacers 49a extends upwardly from the ESL 44 in the vertical direction and laterally covers a corresponding one of the air gap structures 48, so as to permit the corresponding one of the air gap structures 48 to be spaced apart from a corresponding one of the electrically conductive interconnect 53 by the each of the dielectric spacers 49a. The electrically conductive interconnect 54 is disposed between and connected to a corresponding one of the electrically conductive interconnects 411 of the conductive interconnect structure 41 and a corresponding one of the electrically conductive interconnects 53. The electrically conductive interconnect 54 includes a bulk via portion 541 connected to the bulk metal portion 531 of the corresponding one of the electrically conductive interconnects 53, and a barrier layer 542 which is connected to the barrier layer 532 of the corresponding one of the electrically conductive interconnects 53 and which covers a lateral surface and a bottom surface of the bulk via portion 541.

Referring to FIGS. 20 and 28, the method 100C then proceeds to step 10C, where an ESL 55 is formed on the air gap structures 48 and the electrically conductive interconnects 53. The material and process for forming the ESL 55 may be the same as or similar to those for forming the ESL 19 as described in step 8A, and thus, the details thereof are omitted for the sake of brevity.

Referring to FIGS. 20 and 29, the method 100C then proceeds to step 11C, where a conductive interconnect structure 56 is formed. The conductive interconnect structure 56 may include a dielectric layer 561 and an electrically conductive interconnect 562 (e.g., an electrically conductive via contact). The dielectric layer 561 of the conductive interconnect structure 56 is formed on the ESL 55. The material and process for forming the dielectric layer 561 of the conductive interconnect structure 56 are similar to those of the dielectric layer 111 as described in step 1A, and thus, the details thereof are omitted for the sake of brevity. The electrically conductive interconnect 562 of the conductive interconnect structure 56 penetrates the ESL 55 and is disposed on and electrically connected to a corresponding one of the electrically conductive interconnects 53. The material and process for forming the electrically conductive interconnect 562 are similar to those of the first electrically conductive interconnect 112 as described in step 1A, and thus, the details thereof are omitted for the sake of brevity. The conductive interconnect structure 56 may be formed by a damascene process or the RIE process.

In some embodiments of this disclosure, by selectively bonding functionalized polymers to an upper surface of a dielectric layer exposed through trenches formed among electrically conductive interconnects (e.g., metal lines) disposed on the dielectric layer, and by thermal annealing the functionalized polymers after the formation of an interlayer dielectric layer on the functionalized polymers, carbon-based polymer chains of the functionalized polymers are removed to form air gap structures. In addition, by adjusting the molecular weights of the carbon-based polymer chains, the heights of the air gap structures can be controlled and the uniformity of the heights of the air gap structures can be improved, which is conducive to reducing RC delay and electronic interference in a semiconductor device. The air gap structures provided by this disclosure can be formed in trenches that have various critical dimensions and that are formed among the electrically conductive interconnects.

In some embodiments of this disclosure, air gap structures are formed by forming a nanoparticle dispersion layer, which includes a dielectric layer and a plurality of nanoparticles dispersed in the dielectric layer; patterning the nanoparticle dispersion layer; and selectively removing the nanoparticles by, for example, but not limited to, a selective etching process, a wet clean removal process, a baking process, or the like. Each of the air gap structures thus formed includes a dielectric portion and a plurality of nanopores, which are distributed in the dielectric portion and which are spatially communicated with each other. Since the nanopores formed in the air gap structures are formed by removing the nanoparticles, the sizes or the diameters of which can be controlled, the sizes or the diameters of the nanopores can be controlled accordingly. In addition, the air gap structures are formed before electrically conductive interconnects (for example, metal lines) are formed. Therefore, the electrically conductive interconnects will not be damaged. Furthermore, since an etch stop layer is formed below the nanoparticle dispersion layer, and the depths of trenches formed by patterning the nanoparticle dispersion layer can be controlled, the electrically conductive interconnects thus formed have improved electrical performance.

In accordance with some embodiments of the present disclosure, a semiconductor device includes a substrate, a conductive interconnect structure disposed on the substrate, a plurality of air gap structures disposed on the conductive interconnect structure and spaced apart from each other, and a plurality of conductive interconnects disposed on the conductive interconnect structure and alternating with the plurality of the air gap structures. Each of the plurality of the air gap structures includes a dielectric portion and an air gap. The air gap of each of the plurality of the air gap structures is confined by the dielectric portion of the each of the plurality of the air gap structures and two corresponding ones of the plurality of the conductive interconnects.

In accordance with some embodiments of the present disclosure, the dielectric portion is configured as a bottom layer disposed on the conductive interconnect structure and including a functional group of a functionalized polymer. The functional group includes an amino group, a carboxyl group, or a silane-based group.

In accordance with some embodiments of the present disclosure, the air gap includes a plurality of nanopores distributed in the dielectric portion and spatially communicated with each other.

In accordance with some embodiments of the present disclosure, the semiconductor device further includes an etch stop layer and a plurality of dielectric spacers. The etch stop layer is disposed on the conductive interconnect structure, such that the plurality of the air gap structures are separated from the conductive interconnect structure by the etch stop layer. The dielectric spacers extend upwardly from the etch stop layer, such that each of the plurality of the air gap structures is laterally covered by two corresponding ones of the plurality of the dielectric spacers.

In accordance with some embodiments of the present disclosure, a method for manufacturing a semiconductor device includes: forming a plurality of spaced-apart conductive interconnects on a surface of a conductive interconnect structure disposed on a substrate; selectively forming a plurality of functionalized polymers on the surface of the conductive interconnect structure, each of the plurality of the functionalized polymers including a carbon-based polymer chain and a functional group that is bonded to the surface of the conductive interconnect structure, the functional group including an amino group, a carboxyl group, or a silane-based group; forming a first dielectric layer to cover the plurality of the spaced-apart conductive interconnects and the plurality of the functionalized polymers; and removing the carbon-based polymer chain of each of the plurality of the functionalized polymers so as to form a plurality of air gap structures, such that two adjacent ones of the plurality of the spaced-apart conductive interconnects are spaced apart from each other by a corresponding one of the plurality of the air gap structures.

In accordance with some embodiments of the present disclosure, the silane-based group is represented by Formula A,

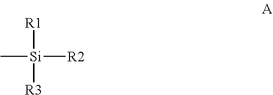

wherein
each of R1, R2, and R3 is a methoxy group, an ethoxy group, or a propoxy group, and R1, R2, and R3 are the same as or different from each other.

In accordance with some embodiments of the present disclosure, the carbon-based polymer chain includes a polymer chain of polymethyl methacrylate, polyimide, or a combination thereof.

In accordance with some embodiments of the present disclosure, the carbon-based polymer chain has a molecular weight ranging from 2000 to 200000.

In accordance with some embodiments of the present disclosure, the conductive interconnect structure includes a second dielectric layer formed with a plurality of hydroxyl groups on a surface of the second dielectric layer, on which the plurality of the spaced-apart conductive interconnects are formed. The plurality of the functionalized polymers are selectively formed on the upper surface of the second dielectric layer by a bonding reaction between the functional group of each of the plurality of the functionalized polymers and a corresponding one of the plurality of the hydroxyl groups.

In accordance with some embodiments of the present disclosure, each of the plurality of the air gap structures includes a bottom layer and an air gap. The bottom layer is disposed on the surface of the conductive interconnect structure and includes the functional group. The air gap is defined by two corresponding ones of the plurality of the spaced-part conductive interconnects, a corresponding portion of the first dielectric layer, and the bottom layer.

In accordance with some embodiments of the present disclosure, a plurality of recesses are formed among the plurality of the spaced-apart conductive interconnects before the first dielectric layer is formed. Each of the recesses is defined by upper portions of two corresponding ones of the plurality of the spaced apart conductive interconnects and corresponding ones of the plurality of the functionalized polymers. The plurality of the recesses are filled with the first dielectric layer in the formation of the first dielectric layer.

In accordance with some embodiments of the present disclosure, a method for manufacturing a semiconductor device includes: forming a nanoparticle dispersion layer over a conductive interconnect structure disposed on a substrate, the nanoparticle dispersion layer including a first dielectric layer and a plurality of nanoparticles dispersed in the first dielectric layer, the first dielectric layer including a first dielectric material; patterning the nanoparticle dispersion layer to form a plurality of trenches in the nanoparticle dispersion layer; and removing the nanoparticles to form a plurality of air gap structures, two adjacent ones of the plurality of the air gap structures being spaced apart from each other by a corresponding one of the plurality of the trenches, each of the plurality of the air gap structures including a dielectric portion and a plurality of nanopores which are distributed in the dielectric portion and which are spatially communicated with each other.

In accordance with some embodiments of the present disclosure, the method for manufacturing a semiconductor device further includes prior to the formation of the nanoparticle dispersion layer, forming an etch stop layer on the conductive interconnect structure, such that the etch stop layer is formed between the conductive interconnect structure and the nanoparticle dispersion layer after the nanoparticle dispersion layer is formed.

In accordance with some embodiments of the present disclosure, the etch stop layer is exposed through the plurality of the trenches after the nanoparticle dispersion layer is patterned.

In accordance with some embodiments of the present disclosure, the method for manufacturing a semiconductor device further includes: conformally forming a dielectric spacer material layer to cover the plurality of the air gap structures and the etch stop layer; and removing portions of the dielectric spacer material layer and portions of the etch stop layer to form a plurality of dielectric spacers extending upwardly from the etch stop layer, such that each of the plurality of the air gap structures is laterally covered by two corresponding ones of the plurality of the dielectric spacers.

In accordance with some embodiments of the present disclosure, the method for manufacturing a semiconductor device further includes: forming a plurality of first conductive interconnects in the plurality of the trenches, respectively, such that each of the plurality of the first conductive interconnects is spaced apart from a corresponding one of the plurality of the air gap structures by a corresponding one of the plurality of the dielectric spacers.

In accordance with some embodiments of the present disclosure, the method for manufacturing a semiconductor device further includes: forming a second dielectric layer on the etch stop layer opposite to the plurality of the air gap structures; forming an opening in the second dielectric layer before the plurality of the first conductive interconnects are formed, the opening being spatially communicated with a corresponding one of the plurality of the trenches; and forming a second conductive interconnect in the opening, the second conductive interconnect being connected to a corresponding one of the plurality of the first conductive interconnects.

In accordance with some embodiments of the present disclosure, each of the plurality of the nanoparticles has a diameter ranging from 10 Å to 100 Å.

In accordance with some embodiments of the present disclosure, the plurality of the nanoparticles includes a carbon-based polymer, a second dielectric material different from the first dielectric material, or a metal-based material.

In accordance with some embodiments of the present disclosure, the plurality of the nanoparticles are removed by a selective etching process, a wet clean removal process, or a baking process.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a conductive interconnect structure disposed on the substrate;
a plurality of air gap structures disposed on the conductive interconnect structure and spaced apart from each other, each of the plurality of the air gap structures including a dielectric portion and an air gap; and
a plurality of conductive interconnects disposed on the conductive interconnect structure and alternating with the plurality of the air gap structures, such that the air gap of each of the plurality of the air gap structures is confined by the dielectric portion of the each of the plurality of the air gap structures and two corresponding ones of the plurality of the conductive interconnects.

2. The semiconductor device as claimed in 1, wherein the dielectric portion is configured as a bottom layer disposed on the conductive interconnect structure and including a functional group of a functionalized polymer, the functional group including a thiol group, an epoxy group, an amino group, a carboxyl group, or a silane-based group.

3. The semiconductor device as claimed in 1, wherein the air gap includes a plurality of nanopores distributed in the dielectric portion and spatially communicated with each other.

4. The semiconductor device as claimed in claim 3, further comprising:
an etch stop layer disposed on the conductive interconnect structure, such that the plurality of the air gap structures are separated from the conductive interconnect structure by the etch stop layer; and
a plurality of dielectric spacers extending upwardly from the etch stop layer, such that each of the plurality of the air gap structures is laterally covered by two corresponding ones of the plurality of the dielectric spacers.

5. A method for manufacturing a semiconductor device, comprising:
forming a plurality of spaced-apart conductive interconnects on a surface of a conductive interconnect structure disposed on a substrate;
selectively forming a plurality of functionalized polymers on the surface of the conductive interconnect structure, each of the plurality of the functionalized polymers including a carbon-based polymer chain and a functional group that is bonded to the surface of the conductive interconnect structure, the functional group including a thiol group, an epoxy group, an amino group, a carboxyl group, or a silane-based group;
forming a first dielectric layer to cover the plurality of the spaced-apart conductive interconnects and the plurality of the functionalized polymers; and
removing the carbon-based polymer chain of each of the plurality of the functionalized polymers so as to form a plurality of air gap structures, such that two adjacent ones of the plurality of the spaced-apart conductive interconnects are spaced apart from each other by a corresponding one of the plurality of the air gap structures.

6. The method as claimed in claim 5, wherein the silane-based group is represented by Formula A, 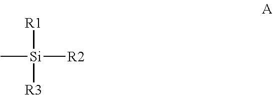
wherein
each of R1, R2, and R3 is a methoxy group, an ethoxy group, or a propoxy group, and R1, R2, and R3 are the same as or different from each other.

7. The method as claimed in claim 5, wherein the carbon-based polymer chain includes a polymer chain of polymethyl methacrylate, polyimide, or a combination thereof.

8. The method as claimed in claim 5, wherein the carbon-based polymer chain has a molecular weight ranging from 2000 to 200000.

9. The method as claimed in claim 5, wherein
the conductive interconnect structure includes a second dielectric layer formed with a plurality of hydroxyl groups on a surface of the second dielectric layer, on which the plurality of the spaced-apart conductive interconnects are formed; and
the plurality of the functionalized polymers are selectively formed on the upper surface of the second dielectric layer by a bonding reaction between the functional group of each of the plurality of the functionalized polymers and a corresponding one of the plurality of the hydroxyl groups.

10. The method as claimed in claim 5, wherein each of the plurality of the air gap structures includes:
a bottom layer disposed on the surface of the conductive interconnect structure and including the functional group, and
an air gap defined by two corresponding ones of the plurality of the spaced-part conductive interconnects, a corresponding portion of the first dielectric layer, and the bottom layer.

11. The method as claimed in claim 5, wherein
a plurality of recesses are formed among the plurality of the spaced-apart conductive interconnects before the first dielectric layer is formed, each of the recesses being defined by upper portions of two corresponding ones of the plurality of the spaced apart conductive interconnects and corresponding ones of the plurality of the functionalized polymers; and
the plurality of the recesses are filled with the first dielectric layer in the formation of the first dielectric layer.

12. A method for manufacturing a semiconductor device, comprising:
forming a nanoparticle dispersion layer over a conductive interconnect structure disposed on a substrate, the nanoparticle dispersion layer including a first dielectric layer and a plurality of nanoparticles dispersed in the first dielectric layer, the first dielectric layer including a first dielectric material;
patterning the nanoparticle dispersion layer to form a plurality of trenches in the nanoparticle dispersion layer; and
removing the nanoparticles to form a plurality of air gap structures, two adjacent ones of the plurality of the air gap structures being spaced apart from each other by a corresponding one of the plurality of the trenches, each of the plurality of the air gap structures including a dielectric portion and a plurality of nanopores which are distributed in the dielectric portion and which are spatially communicated with each other.

13. The method as claimed in claim 12, further comprising prior to the formation of the nanoparticle dispersion layer, forming an etch stop layer on the conductive interconnect structure, such that the etch stop layer is formed between the conductive interconnect structure and the nanoparticle dispersion layer after the nanoparticle dispersion layer is formed.

14. The method as claimed in claim 13, wherein the etch stop layer is exposed through the plurality of the trenches after the nanoparticle dispersion layer is patterned.

15. The method as claimed in claim 14, further comprising:
conformally forming a dielectric spacer material layer to cover the plurality of the air gap structures and the etch stop layer; and
removing portions of the dielectric spacer material layer and portions of the etch stop layer to form a plurality of dielectric spacers extending upwardly from the etch stop layer, such that each of the plurality of the air gap structures is laterally covered by two corresponding ones of the plurality of the dielectric spacers.

16. The method as claimed in claim 15, further comprising forming a plurality of first conductive interconnects in the plurality of the trenches, respectively, such that each of the plurality of the first conductive interconnects is spaced apart from a corresponding one of the plurality of the air gap structures by a corresponding one of the plurality of the dielectric spacers.

17. The method as claimed in claim 16, further comprising:
forming a second dielectric layer on the etch stop layer opposite to the plurality of the air gap structures;
forming an opening in the second dielectric layer before the plurality of the first conductive interconnects are formed, the opening being spatially communicated with a corresponding one of the plurality of the trenches; and
forming a second conductive interconnect in the opening, the second conductive interconnect being connected to a corresponding one of the plurality of the first conductive interconnects.

18. The method as claimed in claim 12, wherein each of the plurality of the nanoparticles has a diameter ranging from 10 Å to 100 Å.

19. The method as claimed in claim 12, wherein the plurality of the nanoparticles includes a carbon-based polymer, a second dielectric material different from the first dielectric material, or a metal-based material.

20. The method as claimed in claim 12, wherein the plurality of the nanoparticles are removed by a selective etching process, a wet clean removal process, or a baking process.
